(19) United States
(12) Patent Application Publication
(10) Pub. No.: US 2021/0195785 A1
(43) Pub. Date: Jun. 24, 2021

(54) SERVER ENCLOSURES INCLUDING TWO POWER BACKPLANES

(71) Applicant: HEWLETT PACKARD ENTERPRISE DEVELOPMENT LP, Houston, TX (US)

(72) Inventors: Vincent Michna, Houston, TX (US); Brian Purcell, Houston, TX (US); David P. Mohr, Houston, TX (US); Chandler Harris, Houston, TX (US)

(21) Appl. No.: 16/077,733

(22) PCT Filed: Jan. 29, 2016
(86) PCT No.: PCT/US2016/015820

§ 371 Date: Aug. 13, 2018

(51) Int. Cl. H05K 7/14; G06F 1/18

(52) U.S. Cl. CPC H05K 7/1492; G06F 1/189; G06F 1/181

(57) ABSTRACT

One example of a server enclosure includes a plurality of slots, a first power backplane, and a second power backplane. Each slot includes a first power connector and a second power connector. The first power backplane is electrically coupled to each of the first power connectors. The second power backplane is electrically coupled to each of the second power connectors.

### BACKGROUND

A plurality of computing devices (e.g., servers), network switches, management modules, power supplies, and cooling devices may be installed within a server enclosure. The power supplies may supply power to the other devices installed within the server enclosure. Alternatively, the server enclosure may receive power from external power supplies and distribute the power to the devices installed within the server enclosure.

### BRIEF DESCRIPTION OF THE DRAWINGS

FIG. 1 is a schematic diagram illustrating one example of a server enclosure.

FIG. 2 is a schematic diagram illustrating one example of the server enclosure of FIG. 1 with installed devices.

FIG. 3 is a schematic diagram illustrating another example of a server enclosure.

FIG. 4 is a block diagram illustrating one example of a system.

FIG. 5 is a flow diagram illustrating one example of a method for fabricating a system.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

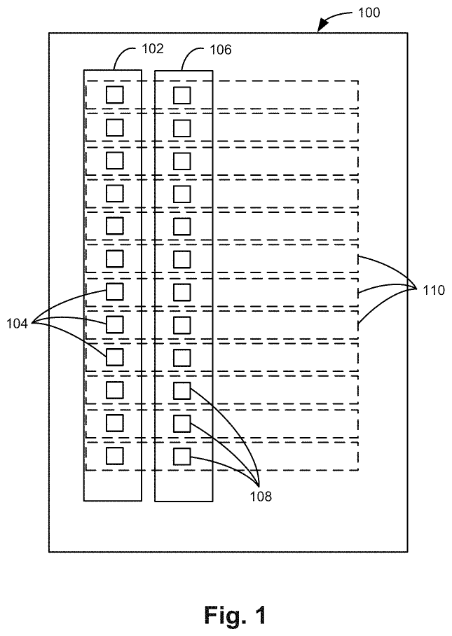

FIG. 1 is a schematic diagram illustrating one example of a server enclosure 100. Enclosure 100 includes a first power backplane 102, a second power backplane 106, and a plurality of slots indicated for example at 110 for receiving devices. First power backplane 102 includes a plurality of first power connectors indicated for example at 104. Each first power connector 104 may be electrically coupled to a first power input of a device installed in a slot 110 corresponding to the first power connector 104. Each first power connector 104 is electrically coupled to a first power supply (not shown) providing first power to first power backplane 102. Second power backplane 106 includes a plurality of second power connectors indicated for example at 108. Each second power connector 108 may be electrically coupled to a second power input of a device installed in a slot 110 corresponding to the second power connector 108. Each second power connector 108 is electrically coupled to a second power supply (not shown) providing second power to second power backplane 106.

The power distributed by first power backplane 102 to each first power connector 104 has a voltage less than the voltage of the power distributed by second power backplane 106 to each second power connector 108. In one example, first power backplane 102 is a low voltage direct current (LVDC) backplane and second power backplane 106 is a high voltage direct current (HVDC) backplane. The HVDC power distributed by the HVDC backplane may have a voltage within the range between 360 VDC and 380 VDC, and the LVDC power distributed by the LVDC backplane may have a voltage within the range between 12 VDC and 48 VDC. In other examples, the HVDC power and the LVDC power may have other suitable voltages where the voltage of the HVDC power is greater than the voltage of the LVDC power.

A device installed in a slot 110 may be powered by first power backplane 102 or second power backplane 106. For example, a higher power device (e.g., liquid cooled server) may be powered by second power backplane 106 while a lower power device (e.g., network switch, air cooled server) may be powered by first power backplane 102. A device installed in a slot 110 may also be electrically coupled to both first power backplane 102 and second power backplane 106. In this case, first power backplane 102 provides first power to a first portion of the device and second power backplane 106 provides second power to a second portion of the device.

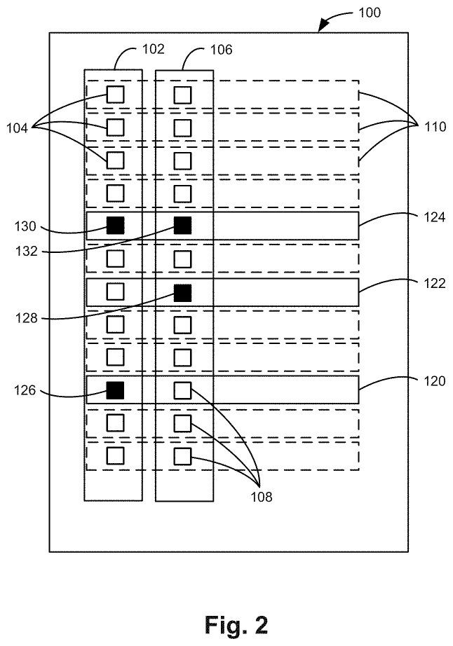

FIG. 2 is a schematic diagram illustrating one example of server enclosure 100 previously described and illustrated with reference to FIG. 1 with installed devices 120, 122, and 124. Each device 120, 122, and 124 is installed in a slot 110. Device 120 includes a first power input electrically coupled to a first power connector 104 of first power backplane 102 as indicated at 126. Device 120 receives first power from first power backplane 102 to power device 120. Device 120 is electrically isolated from second power backplane 106. Device 122 includes a second power input electrically coupled to a second power connector 108 of second power backplane 106 as indicated at 128. Device 122 receives second power from second power backplane 106 to power device 122. Device 122 is electrically isolated from first power backplane 102.

Device 124 includes a first power input electrically coupled to a first power connector 104 of first power backplane 102 as indicated at 130. Device 124 also includes a second power input electrically coupled to a second power connector 108 of second power backplane 106 as indicated at 132. Device 124 receives first power from first power backplane 102 to power a first portion of device 124. Device 124 receives second power from second power backplane 106 to power a second portion of device 124.

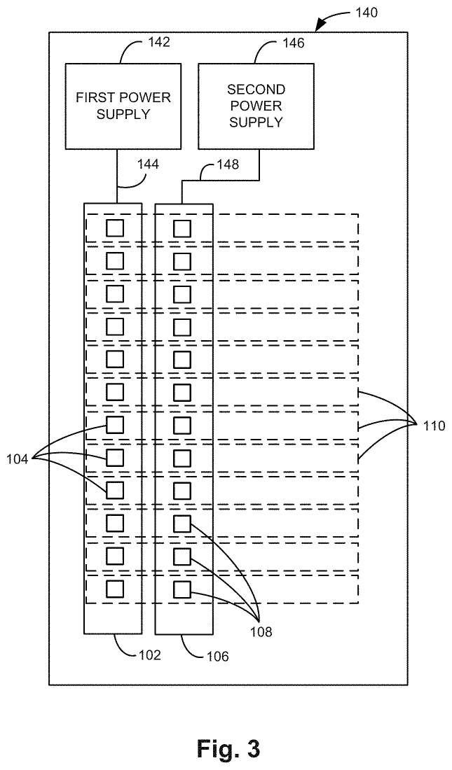

FIG. 3 is a schematic diagram illustrating another example of a server enclosure 140. Server enclosure 140 includes a first power backplane 102, a second power backplane 106, and a plurality of slots 110 as previously described and illustrated with reference to FIG. 1. In addition, server enclosure 140 includes a first power supply 142 and a second power supply 146. First power supply 142 is electrically coupled to first power backplane 102 through a power transmission path 144. Second power supply 146 is electrically coupled to second power backplane 106 through a power transmission path 148. In one example, first power supply 142 converts line power to provide LVDC power to first power backplane 102 and second power supply 146 converts line power to provide HVDC power to second power backplane 106. In other examples, first power supply 142 provides power to first power backplane 102 having another suitable voltage less than a voltage of power provided to second power backplane 106 by second power supply 146.

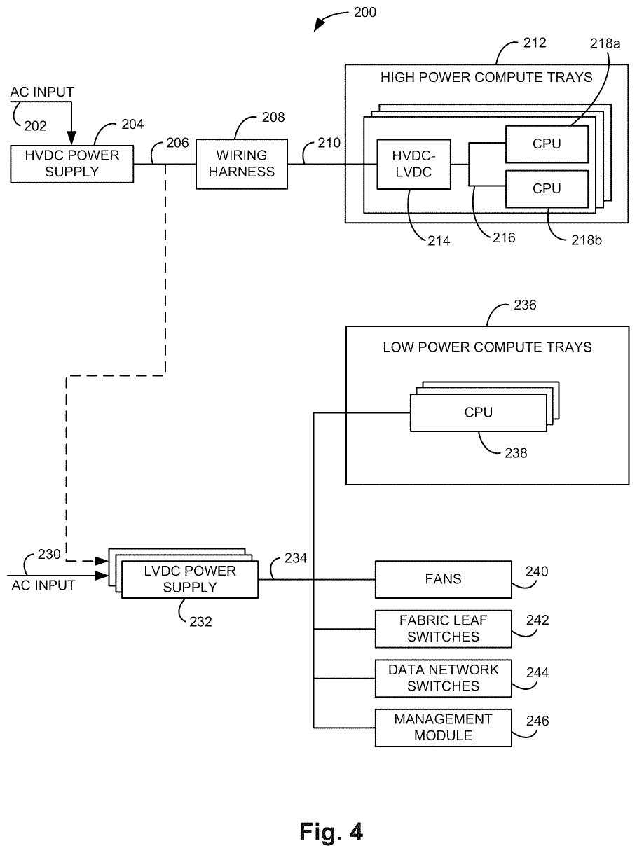

FIG. 4 is a block diagram illustrating one example of a system 200. System 200 may be installed into a server enclosure, such as server enclosure 100 previously described and illustrated with reference to FIG. 1. System 200 includes a HVDC power supply 204, a wiring harness 208, high power compute trays 212, at least one LVDC power supply 232, low power compute trays 236, fans 240, fabric leaf switches 242, data network switches 244, and a management module 246.

The input of HVDC power supply 204 receives an AC input (e.g., line power) through a power transmission path 202. The output of HVDC power supply 204 is electrically coupled to wiring harness 208 through a HVDC power transmission path 206. In one example, the output of HVDC power supply 204 is also electrically coupled to the input of the at least one LVDC power supply 232. In other examples, the output of HVDC power supply 204 is not electrically coupled to the input of the at least one LVDC power supply 232. HVDC power supply 204 converts AC line power to provide HVDC power on HVDC power transmission path 206. Wiring harness 208 is electrically coupled to high power compute trays 212 through a HVDC power transmission path 210. Wiring harness 208 passes HVDC power from HVDC power supply 204 to HVDC transmission path 210. In one example, wiring harness 208 and HVDC power transmission path 210 include a power backplane electrically coupled to a plurality of power connectors, such as second power backplane 106 and second power connectors 108 previously described and illustrated with reference to FIG. 1.

Each high power compute tray includes a HVDC to LVDC converter 214 and central processing units (CPUs) 218a and 218b. The input of the HVDC to LVDC converter 214 of each high power compute tray receives HVDC power from HVDC power supply 204. The HVDC to LVDC converter 214 of each high power compute tray converts the received HVDC power to provide LVDC power to each CPU 218a and 218b within the corresponding high power compute tray through a LVDC power transmission path 216. In one example, high power compute trays 212 are liquid cooled. In other examples, high power compute trays 212 may have other suitable configurations (e.g., a different number of CPUs) but in each example may include a HVDC to LVDC converter.

The input of the at least one LVDC power supply 232 receives an AC input (e.g., line power) through a power transmission path 230. Alternatively, or in addition, the input of the at least one LVDC power supply 232 receives HVDC power from HVDC power supply 204. The output of the at least one LVDC power supply 232 is electrically coupled to at least one of low power compute trays 236, fans 240, fabric leaf switches 242, data network switches 244, and management module 246 through a LVDC power transmission path 234. The at least one LVDC power supply 232 converts AC line power and/or HVDC power to provide LVDC power on LVDC power transmission path 234. In one example, LVDC power transmission path 234 includes a power backplane electrically coupled to a plurality of power connectors, such as first power backplane 102 and second power connectors 104 previously described and illustrated with reference to FIG. 1.

In one example, each low power compute tray includes a CPU 238. The LVDC power on LVDC power transmission path 234 powers each CPU 238. In one example, low power compute trays 236 are air cooled. In other examples, low power compute trays 238 may have other suitable configurations but in each example receive LVDC power for operating each low power compute tray. Fans 240, fabric leaf switches 242, data network switches 244, and/or management module 246 receive LVDC power for operating each device.

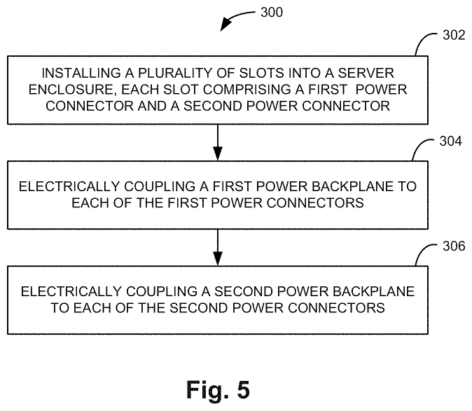

FIG. 5 is a flow diagram illustrating one example of a method 300 for fabricating a system. At 302, method 300 includes installing a plurality of slots into a server enclosure, each slot comprising a first power connector and a second power connector. At 304, method 300 includes electrically coupling a first power backplane to each of the first power connectors. At 306, method 300 includes electrically coupling a second power backplane to each of the second power connectors.

In one example, the method further includes installing a first device into a first slot of the plurality of slots to electrically couple the first device to the first power connector of the first slot. The method may also include installing a second device into a second slot of the plurality of slots to electrically couple the second device to the second power connector of the second slot. In addition, the method may further include installing a power supply into the server enclosure to convert line power to provide low voltage direct current (LVDC) power to the first power backplane. Further, the method may include installing a power supply into the server enclosure to convert line power to provide high voltage direct current (HVDC) power to the second power backplane.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A server enclosure comprising:
a plurality of slots, each slot comprising a first power connector and a second power connector;
a first power backplane electrically coupled to each of the first power connectors; and
a second power backplane electrically coupled to each of the second power connectors.

2. The server enclosure of claim 1, further comprising:
a power supply electrically coupled to the first power backplane, the power supply to convert line power to low voltage direct current (LVDC) power.

3. The server enclosure of claim 1, further comprising:
a power supply electrically coupled to the second power backplane, the power supply to convert line power to high voltage direct current (HVDC) power.

4. The server enclosure of claim 1, wherein the first power backplane distributes between 12 VDC and 48 VDC to each first power connector.

5. The server enclosure of claim 1, wherein the second power backplane distributes between 360 VDC and 380 VDC to each second power connector.

6. A system comprising:
a server enclosure comprising:
a plurality of slots, each slot comprising a first power connector and a second power connector;
a first power backplane electrically coupled to each of the first power connectors; and
a second power backplane electrically coupled to each of the second power connectors;
a first device installed in a first slot of the plurality of slots, the first device electrically coupled to the first power connector of the first slot; and
a second device installed in a second slot of the plurality of slots, the second device electrically coupled to the second power connector of the second slot.

7. The system of claim 6, wherein the first device comprises a high voltage direct current (HVDC) to low voltage direct current (LVDC) converter, and
wherein the first device is electrically isolated from the second power backplane.

8. The system of claim 6, further comprising:
a third device installed in a third slot of the plurality of slots, the third device electrically coupled to the first power connector and the second power connector.

9. The system of claim 6, further comprising:
a power supply to convert line power to provide LVDC power to the first power backplane.

10. The system of claim 6, further comprising:
a power supply to convert line power to provide HVDC power to the second power backplane.

11. A method comprising:
installing a plurality of slots into a server enclosure, each slot comprising a first power connector and a second power connector;
electrically coupling a first power backplane to each of the first power connectors; and
electrically coupling a second power backplane to each of the second power connectors.

12. The method of claim 11, further comprising:
installing a device into a first slot of the plurality of slots to electrically couple the device to the first power connector of the first slot.

13. The method of claim 11, further comprising:
installing a device into a first slot of the plurality of slots to electrically couple the device to the second power connector of the first slot.

14. The method of claim 11, further comprising:
installing a power supply into the server enclosure to convert line power to provide low voltage direct current (LVDC) power to the first power backplane.

15. The method of claim 11, further comprising:
installing a power supply into the server enclosure to convert line power to provide high voltage direct current (HVDC) power to the second power backplane.
